(19) United States
(12) Patent Application Publication
(10) Pub. No.: US 2004/0115945 A1
(43) Pub. Date: Jun. 17, 2004

(54) Using an electron beam to write phase change memory devices

(76) Inventors: Tyler A. Lowrey, San Jose, CA (US); Stephen Hudgens, Santa Clara, CA (US)

Correspondence Address: TROP PRUNER & HU, PC, 8554 KATY FREEWAY, SUITE 100, HOUSTON, TX, 77024, US

(21) Appl. No.: 10/319,098

(22) Filed: Dec. 13, 2002

(51) Int. Cl. H01L 21/311

(52) U.S. Cl. 438/700

(57) ABSTRACT

Phase change memories may be made with relatively small pore sizes using electron beam lithography. An electrode may be covered with a relatively thin insulator, which may be patterned using direct write electron beam lithography.

### BACKGROUND

This invention relates generally to electronic memories and particularly to electronic memories that use phase change material.

Phase change materials may exhibit at least two different states. The states may be called the amorphous and crystalline states. Transitions between these states may be selectively initiated. The states may be distinguished because the amorphous state generally exhibits higher resistivity than the crystalline state. The amorphous state involves a more disordered atomic structure. Generally any phase change material may be utilized. In some embodiments, however, thin-film chalcogenide alloy materials may be particularly suitable.

The phase change may be induced reversibly. Therefore, the memory may change from the amorphous to the crystalline state and may revert back to the amorphous state thereafter, or vice versa, in response to temperature changes. In effect, each memory cell may be thought of as a programmable resistor, which reversibly changes between higher and lower resistance states. The phase change may be induced by resistive heating.

A phase change material may be formed within a passage or pore through an insulator. The phase change material may be coupled to upper and lower electrodes on either end of the pore.

Ideally, the area of contact between the lower electrode and phase change material should be made as small as possible. This is because the energy required to program a memory element to either state is a strong function of the contact area. Ideally, the minimum amount of electrical current is supplied to each device to make the memory as power conserving as possible.

Thus, there is a need for better ways to reduce the effective size of the lower electrode in phase change memories.

### BRIEF DESCRIPTION OF THE DRAWINGS

FIG. 1 is an enlarged, partial cross-sectional view of one embodiment of the present invention in the course of fabrication;

FIG. 2 is an enlarged, partial cross-sectional view corresponding to FIG. 1 at a subsequent stage of manufacture in accordance with one embodiment of the present invention;

FIG. 3 is an enlarged, partial cross-sectional view corresponding to FIG. 2 at a subsequent stage of manufacture;

FIG. 4 is an enlarged, partial cross-sectional view in accordance with one embodiment of the present invention at a subsequent stage of manufacture;

FIG. 5 is an enlarged, partial cross-sectional view in accordance with one embodiment of the present invention shown in FIG. 3 at a subsequent stage of manufacture;

FIG. 6 is a schematic depiction of an electron beam writing apparatus in accordance with one embodiment of the present invention; and

FIG. 7 is a schematic system depiction of one embodiment of the present invention.

### DETAILED DESCRIPTION

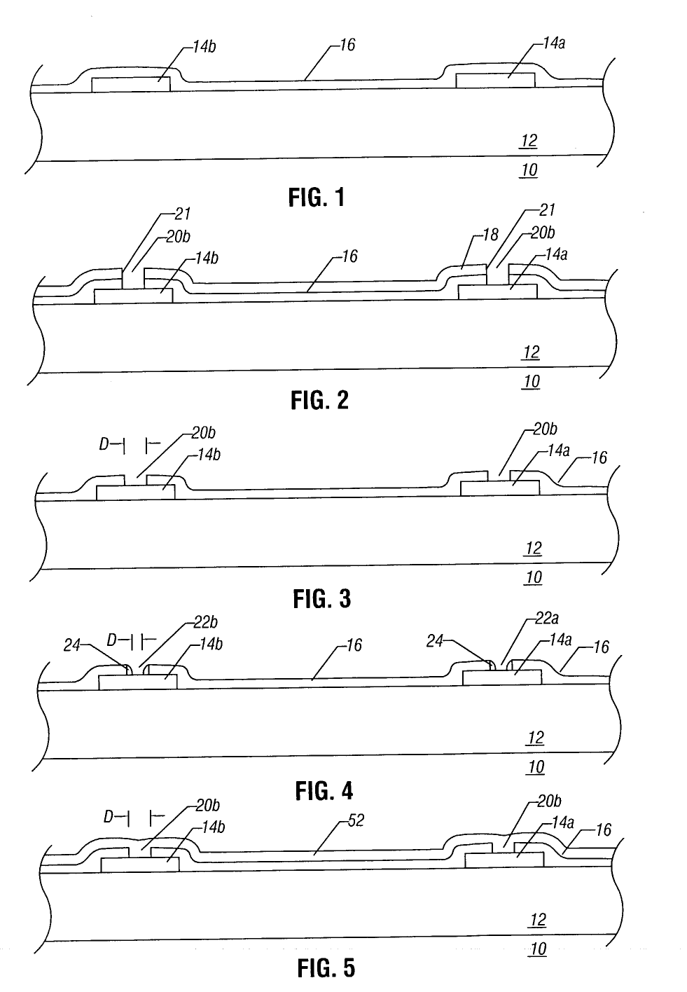

Referring to FIG. 1, a semiconductor substrate 10 may have an insulator 12 formed over the substrate 10. Over the insulator 12 may be a lower electrode 14a or 14b of a phase change memory. The lower electrode 14 may be coupled to a suitable source of potential to supply an electric current across a phase change material (not shown in FIG. 1) that may be positioned between the electrode 14 and an upper electrode (not shown).

A relatively thin insulator 16 may be formed over each of the lower electrodes 14a and the substrate 10. Any of a variety of known insulators may be utilized as a thin insulator 16. The thin insulator 16 may have a thickness in the range of 25 to 500 Angstroms in some embodiments of the present invention.

Referring to FIG. 2, the lower electrode 14 may be covered by an electron beam resist 18. The resulting structure may then be exposed to an electron beam direct write lithography system to pattern small pores or vias 20a and 20b down to each lower electrode 14. For example, in one embodiment of the present invention, Gaussian Vector beam writing may be utilized. The vias 20 may be formed having a diameter on the order of 80 to about 500 Angstroms in one embodiment.

After the intended regions of the vias are exposed in the resist 18, an opening 21 in the resist 18 may be formed. An etching process may form the vias 20 in the insulator 16, using the resist openings 21 as a mask to enable etching of the thin insulator 16 down to the electrode 14.

Next, referring to FIG. 3, the resist 18 may be stripped. This reveals the vias 20b and 20a in the thin insulator 16 which may have a diameter indicated as “D”. The diameter D is a function of the resolution of the electron beam and, with current technology, may be in the range of 80 to about 500 Angstroms. The dimension D is considerably smaller compared to the prior art for dramatically improved phase change memory device performance. In addition, the via 20 aspect ratio may be preserved at one or less to promote good conformal deposition of the phase change material in subsequent steps.

In some embodiments of the present invention, by using electron beam direct write, the need for a spacer within the via 20 may be eliminated. Conventionally, spacers may be provided to further reduce the size of the phase change material exposed to the electrode 14. In particular, since the phase change material is deposited into the via 20, the smaller the via 20, the more effective the phase change material memory. To this end, side wall spacers may be formed within the via 20 in order to further decrease the amount of the lower electrode that is exposed to the phase change material.

In some embodiments of the present invention then, spacer deposition is not needed. Commonly, spacer depositions may occur at 650 to 800° C. Eliminating the spacer deposition steps allows lower temperature processing of the phase change memory. With lower temperatures, post-aluminum processes where the phase change memory may be built after metal layers have been formed, are more feasible.

However, in another embodiment of the present invention, even with the smaller via 20, side wall spacers may be utilized. As shown in FIG. 4, a conformal insulator, such as silicon oxide or nitride, may be deposited onto the horizontal and vertical surfaces of the structure shown in FIG. 3. The conformal insulator may be anisotropically etched to formed the spacers 24 shown in FIG. 4. The dimension D may then be made even smaller, for example, on the order of 25 to about 400 Angstroms in some embodiments.

After the structure shown in FIG. 3 or 4 is complete, the phase change material 52 may be deposited or otherwise formed into the vias 20 or 22 as shown in FIG. 5. Thereafter, an upper electrode (not shown) may be applied and the otherwise conventional steps may be completed.

One potential disadvantage of using direct write electron beam lithography is its slower throughput. This slower throughput results in less productivity for the capital investment and, ultimately, higher product cost. However, in some embodiments of the present invention, this disadvantage of electron beam lithography may be less significant. Firstly, the use of the direct write electron beam lithography is limited to the device structure in a single lithographic level in some embodiments. Other pattern levels of the structure can be done using higher throughput conventional lithography in those embodiments. Secondly, for the particular level being defined by electron beam direct write, the features to be patterned all consist of minimum size vias in some embodiments. No lines, spaces, or large area devices need be delineated in those embodiments. Further, these vias may all be of the same size in some embodiments. As a result, the time needed for electron beam scanning to paint variably shaped features is unnecessary in some embodiments of the present invention. Thirdly, the vias may be located in a regular arrayed pattern in some embodiments. Memory cells are generally laid out in repeating regular x,y arrays. Thus, the spacing for each via in the x and y directions may be constant. This regularity may result in faster set up times for faster electron beam write jobs. Fourthly, this application only involves printing relatively small patterned densities. This pattern density, given current technologies, is 0.01 percent to 10 percent of the wafer surface that needs to be exposed to the electron beam.

Therefore, the slower throughput may be less of a disadvantage in connection with phase change memories. However, in many cases, any throughput disadvantage may be acceptable in view of any performance advantages achieved using electron beam writing.

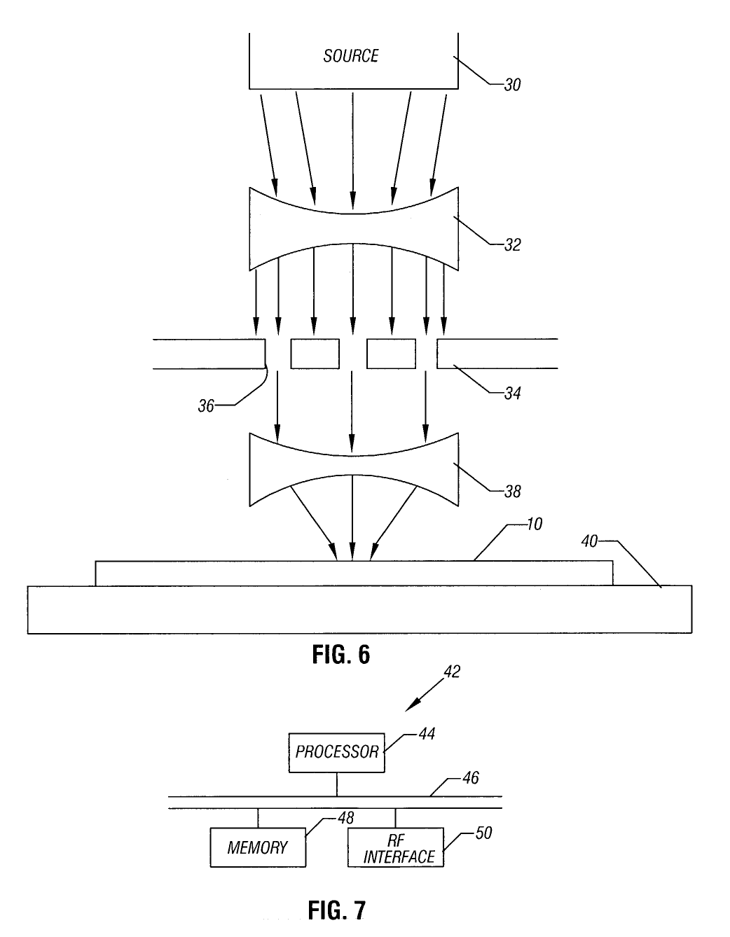

Nevertheless, referring to FIG. 6, in accordance with one embodiment of the present invention, the electron beam writing column may include an electron beam source 30. The beam produced by the source 30 is passed through a focal lens or lenses 32 and collimated in one embodiment. Next, a perforated plate 34 is placed in series with the beam. The plate 34 may be composed of a regular two-dimensional arrayed set of apertures providing for parallel writes of an array of fixed width electron beams. As a result, a number of vias 20 may be simultaneously written, as indicated. After the beam is passed through the plate 34 it may be further focused and/or image reduced using an electron beam lens 38. The substrate 10 may be a semiconductor wafer supported on a chuck 40.

Referring to FIG. 7, a processor-based system 42, such as a cellular telephone as one example, may include a processor 44 coupled to a host bus 46. The bus 46 may be coupled to a phase change memory 48 made in accordance with the description provided herein. Also coupled to the bus 46 in some embodiments, may be a wireless interface 50 that may be a radio frequency interface. The interface 50 may be a wireless transceiver, an antenna, or a cellular phone, to mention a few examples. While an embodiment is disclosed in which a cellular telephone or other radio frequency device is illustrated, the present invention is in no way limited to any particular applications and may be utilized in a variety of applications amenable to the use of semiconductor memories.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a layer over an electrode of a phase change memory; and
patterning said layer using electron beam lithography.

2. The method of claim 1 wherein forming a layer includes forming an insulator layer.

3. The method of claim 2 including forming an insulator layer having a thickness less than about 500 Angstroms.

4. The method of claim 1 including covering said layer with an electron beam resist and exposing said resist to an electron beam.

5. The method of claim 4 including using an aperture formed in said resist as a mask to form a via through said layer.

6. The method of claim 5 including forming a via through said layer that is less than about 500 Angstroms.

7. The method of claim 6 including forming a via through said layer that is less than about 500 Angstroms deep and less than 500 Angstroms wide.

8. The method of claim 1 wherein patterning said layer includes forming a plurality of vias through said layer having an aspect ratio of not more than one.

9. The method of claim 1 including patterning said layer using said electron beam to form a via having a width in a direction transverse to the direction of said electron beam which is less than about 500 Angstroms.

10. The method of claim 9 including depositing a phase change material in said via.

11. The method of claim 1 including using electron beam lithography to form a via through said layer, and forming a side wall spacer in said via.

12. The method of claim 11 including defining an opening using said side wall spacer, said opening having a width of less than about 400 Angstroms.

13. A phase change memory comprising:
a substrate;
a lower electrode formed over said substrate; and
a phase change material positioned over said lower electrode and contacting the lower electrode through an opening having a dimension of less than about 500 Angstroms.

14. The memory of claim 13 wherein said dimension is less than about 400 Angstroms.

15. The memory of claim 13 including an insulator layer over said lower electrode, said insulator layer having an opening with a dimension of less than about 500 Angstroms, said opening being filled at least in part with phase change material.

16. The memory of claim 15 wherein said opening is partially filled with a side wall spacer.

17. The memory of claim 16 wherein the phase change material has a dimension of less than about 400 Angstroms in contact with said lower electrode.

18. A method comprising:
forming an electron beam;
positioning a structure in the path of said beam, said structure including a plurality of passages;
forming a plurality of sub-beams from said beam by causing said beam to pass through said passages;
defining a plurality of vias with said sub-beams; and
filling said vias with a phase change material.

19. The method of claim 18 including exposing a resist to said beam, and patterning and removing said resist.

20. The method of claim 19 including using said resist to form a via through an insulator layer over the lower electrode of a phase change memory.

21. The method of claim 18 including forming a via to allow a phase change material to contact an electrode of a phase change memory such that said via has a dimension of less than 500 Angstroms.

22. The method of claim 18 including forming a layer over an electrode of a phase change memory and patterning said layer using said sub-beams.

23. The method of claim 22 wherein forming a layer includes forming an insulating layer.

24. An electron beam lithography apparatus comprising:
a beam source; and
a plate positionable within the beam of an electron beam lithography apparatus, said plate having a plurality of holes to form a plurality of sub-beams when the beam exposes said plate.

25. The apparatus of claim 24 including a chuck to hold a semiconductor wafer.

26. The apparatus of claim 24 wherein said holes in said plate are arranged to form the pores of a phase change memory.

27. The apparatus of claim 24 wherein said holes have a dimension of less than about 500 Angstroms.

28. The apparatus of claim 27 wherein said holes are circular and said dimension is a diameter.

29. A system comprising:
a processor;
a memory coupled to said processor, said memory including a substrate, a lower electrode formed over said substrate, and a phase change material positioned over said lower electrode and contacting the lower electrode through an opening having a dimension of less than about 500 Angstroms; and
a wireless interface coupled to said processor.

30. The system of claim 29 wherein said dimension is less than about 400 Angstroms.

31. The system of claim 29 including an insulator layer over said lower electrode, said insulator layer having an opening with a dimension of less than about 500 Angstroms, said opening being filled at least in part with phase change material.

32. The system of claim 31 wherein said opening is partially filled with a side wall spacer.
